(19) United States
(12) Patent Application Publication
(10) Pub. No.: US 2026/0342117 A1
(43) Pub. Date: Oct. 29, 2026

(54) POWER MANAGEMENT BASED UPON BATTERY POWER AVAILABLE (BPA)

(71) Applicant: QUALCOMM Incorporated, San Diego, CA (US)

(72) Inventors: Run Bin Yu, San Leandro, CA (US); Louis Louie, San Diego, CA (US); Eric Mikuteit, San Diego, CA (US); Todd Robert Sutton, Del Mar, CA (US); Melanie Dolores Oclima, San Diego, CA (US); Ronald Alton, Oceanside, CA (US); Chunmei Sun, San Diego, CA (US)

(21) Appl. No.: 19/187,778

(22) Filed: Apr. 23, 2025

(51) Int. Cl. H02J 7/80; G06F 1/26

(52) U.S. Cl. CPC H02J 7/80; G06F 1/26

(57) ABSTRACT

This disclosure provides systems, methods, and devices for improved circuitry that supports proactive device performance and battery management. In a first aspect, a method of power management for a device includes receiving a voltage value of a battery for a device; determining a first battery power available based on the voltage value for a first future load duration; determining a second battery power available based on the voltage value for a second future load duration that is different from the first future load duration, and adjusting at least one parameter of operation of the device powered from the battery based on the first battery power available and the second battery available. Other aspects and features are also claimed and described.

### TECHNICAL FIELD

Aspects of the present disclosure relate generally to integrated circuits, and more particularly, to integrated circuits for improving system on chips (SoCs). Some features may enable and provide improved device and battery performance through proactive performance and battery management.

### INTRODUCTION

Batteries power a variety of different devices. Batteries are often used to power devices whether or not a stationary power source is available. Battery performance can be dependent on the composition of the battery and associated properties. Device performance can also be dependent on battery performance. The amount of current that can be drawn from a battery impacts the maximum performance of individual components in the device, thus affecting the responsiveness of the device. If a device requires a greater current than can be supplied, the device may experience brown outs or other failures and shutdowns. Therefore, managing battery and device performance is important to achieve optimal battery and device performance.

In the current landscape of battery management systems, a predominant approach involves reactively and dramatically reducing device performance once a sufficiently low state of charge is reached with no regard to future device demands. This reactive approach comes with inherent limitations for managing battery and device performance, particularly in low state of charge, high impedance, or cold condition scenarios.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Battery performance in a device may be better managed by managing power consumption in the device in accordance with future determinations of battery performance. Measurement of a battery characteristic, such as a voltage across terminals of the battery, may be used to predict future battery performance. For example, a battery model may be determined based on the measured battery characteristic and/or calibration information for the battery. The battery model may be used to determine a battery power available (BPA) value for a future time, in which the BPA value is indicative of an output current capability of the battery at that future time. The BPA value may be used to adjust one or more parameters of operation of the device powered by the battery. By using a future-oriented BPA prediction based on a battery model, device power management is better optimized by providing for sustained long-term performance, reducing shutdowns caused by voltage drops at low battery levels, and providing early warnings of power shortages, all of which enhance reliability, particularly in extreme conditions.

In some embodiments, two or more BPA values may be determined for the battery corresponding to different times in the future. The two or more BPA values may provide a more accurate indication of battery performance such that power management in the device can more accurately control components of the device without exceeding the capabilities of the battery that could lead to a brown-out condition that adversely impacts a user experience of the device resulting from errors or shut down in the device. Further, power management in the device can maximize the distribution of available power from the battery to components of the device to maximize operational performance within the limits of the battery. In some embodiments, the two BPA values may reflect an immediate BPA and an average BPA. In some embodiments, the two BPA values may reflect a short-term BPA and a long-term BPA. The time periods corresponding to the two BPA values may be an order of magnitude different, such as when the short-term BPA reflects a BPA for the next 100 milliseconds and the long-term BPA reflects a BPA for the next 2 seconds. The use of two different BPA values reflecting future battery capability provides better power management in the device, particularly when the battery is at low charge levels resulting in lower battery terminal voltage and greater discrepancy between immediate BPA and sustained BPA.

Additional details regarding the determination of the BPA values for various embodiments of this disclosure are described in the detailed description that follows.

In one aspect of the disclosure, a method for dynamically indicating impending power shortage conditions includes determining a first battery power available based on a voltage, a current, and a temperature value for a first future load duration; determining a second battery power available based on the voltage, the current, and the temperature values for a second future load duration that is different from the first future load duration; and adjusting at least one parameter of operation of a device powered from a battery based on the first battery power available and the second battery available.

In an additional aspect of the disclosure, an apparatus includes a memory storing processor-readable code; and one or more processors coupled to the memory, the one or more processors configured to execute the processor-readable code to cause the one or more processors to: determine a first battery power available based on a voltage, a current, and a temperature value for a first future load duration; determine a second battery power available based on the voltage, the current, and the temperature values for a second future load duration that is different from the first future load duration; and adjust at least one parameter of operation of a device powered from a battery based on the first battery power available and the second battery available.

In an additional aspect of the disclosure, an mobile device includes a silicon anode battery, a memory storing processor-readable code; and one or more processors coupled to the memory, the one or more processors configured to execute the processor-readable code to cause the one or more processors to: determine a first battery power available of the silicon anode battery based on a voltage, a current and a temperature value for a first future load duration; determine a second battery power available of the silicon anode battery based on the voltage, the current, and the temperature values for a second future load duration that is different from the first future load duration; and adjusting at least one parameter of operation of the mobile device powered from the silicon anode battery based on the first battery power available and the second battery available.

The integrated circuits and System on Chips (SoCs) described herein may be used for processing of various kinds of data, including audio signal processing, video processing, artificial intelligence (AI) processing, mathematical computations, database processing, image processing, and other kinds of data processing. These integrated circuits and/or SoCs can be incorporated into a wide variety of devices. By way of example, they may be incorporated into stand-alone audio devices, such as entertainment devices and personal media players, wireless communication device handsets such as mobile telephones, cellular or satellite radio telephones, personal digital assistants (PDAs), tablets, gaming devices, computing devices such as webcams, video surveillance cameras, or other devices that process data using processing circuitry (e.g., application specific integrated circuits (ASICs), digital signal processors (DSP), graphics processing unit (GPU), or central processing units (CPU)).

In some aspects, a device may include a digital signal processor or a processor (e.g., an application processor) including specific functionality for data processing. Operations on different kinds of data may be performed by different processors, or various operations may be split between the various data processing circuitry (e.g., ASICs, DSP, GPU, CPU, NPU). In some embodiments, the methods and techniques disclosed herein may be adapted for use in a neural signal processor (NSP) in which one or more parameters of data processing are controlled based on output from a machine learning (ML) model executed by the NSP.

Other aspects, features, and implementations will become apparent to those of ordinary skill in the art, upon reviewing the following description of specific, exemplary aspects in conjunction with the accompanying figures. While features may be discussed relative to certain aspects and figures below, various aspects may include one or more of the advantageous features discussed herein. In other words, while one or more aspects may be discussed as having certain advantageous features, one or more of such features may also be used in accordance with the various aspects. In similar fashion, while exemplary aspects may be discussed below as device, system, or method aspects, the exemplary aspects may be implemented in various devices, systems, and methods.

The method may be embedded in a computer-readable medium as computer program code comprising instructions that cause a processor to perform the steps of the method. In some embodiments, the processor may be part of a mobile device including a first network adaptor configured to transmit data, such as images or videos (with associated or embedded sounds) in a recording or as streaming data, over a first network connection of a plurality of network connections; and a processor coupled to the first network adaptor and the memory. The processor may cause the transmission of output image frames described herein over a wireless communications network such as a 5G NR communication network.

The foregoing has outlined, rather broadly, the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows a block diagram of a system-on-chip (SoC) according to one or more aspects of this disclosure.

FIG. 2 is a block diagram illustrating an example implementation of aspects of this disclosure in a mobile device according to one or more aspects of the disclosure.

FIG. 3 shows a flow chart of an example method for power management of a device according to one or more aspects of this disclosure.

FIG. 4 is a graph illustrating device performance over time according to some embodiments of the disclosure.

Like reference numbers and designations in the various drawings indicate like elements.

### DETAILED DESCRIPTION

The present disclosure provides systems, apparatus, methods, and computer-readable media that support improved integrated circuit operation, including techniques for dynamically indicating impending power shortage conditions, particularly in extreme operating conditions and proactively limiting device performance to prevent unintended shutdowns and failures by providing an early warning.

Current battery management systems employ a reactive approach. This reactive approach employs a reactive battery control limit rather than a proactive future battery power available. Due to the chemical and structural characteristics, the battery's internal impedance ramps up significantly in low state of charge ranges and more rapidly if temperature is low. Under these conditions managing system power is important because unmanaged system loads can lead to large voltage drops dragging down system voltage causing a system brown out.

Conventional battery management systems are based on reactive battery control limits to prevent unexpected shutdown in this scenario. As battery voltage gets close to reactive battery control limit thresholds, more frequent interruptions to device performance occur related to reactive battery control limits. Consequently, a reactive battery control limit approach results in a high degree of variability in device performance as it primarily depends on the current state of charge of a battery. A reactive battery control limit also causes unwanted performance fluctuations during dynamic loads and at times of elevated battery impedances. A reactive battery control limit approach also requires high thresholds to effectively manage battery levels and device performance. A reactive battery control limit also is unable to effectively access batteries with low voltage levels or during high impedance values. A reactive battery control limit is also unable to effectively access batteries with high energy densities at lower battery voltages such as in Si-anode batteries. A reactive battery control limit is also unable to optimally manage battery and device performance in extreme conditions such as in cold conditions. Shortcomings mentioned here are only representative and are included to highlight problems that the inventors have identified with respect to existing devices and sought to improve upon. Aspects of devices described below may address some or all of the shortcomings as well as others known in the art. Aspects of the improved devices described herein may present other benefits than, and be used in other applications than, those described above.

Particular implementations of the subject matter described in this disclosure may be implemented to realize one or more of the following potential advantages or benefits. In some aspects, the present disclosure provides techniques to help a device optimally plan power limitations in advance. The present disclosure also provides techniques to gradually and granularly adjust performance limitations to access high energy densities available in lower battery voltage ranges such as in Si-Anode batteries. The present disclosure also provides techniques for improved battery life and increased device performance. The present disclosure also provides efficient extraction of battery charge in low battery voltage and high battery impedance scenarios. The present disclosure also provides techniques to optimally scale to available battery capacity. The present disclosure also provides enhanced improvements in lower battery state of charges where reactive battery control limits are primarily implemented. The present disclosure also provides techniques for managing dynamic device loads. The present disclosure also provides that any system power drawn within battery power available limits will not cause the device to brown out.

The detailed description set forth below, in connection with the appended drawings to which the text references, is intended as a description of various embodiments and is not intended to limit the scope of the disclosure. Rather, the detailed description includes specific details for the purpose of providing a thorough understanding of the subject matter of this disclosure. It will be apparent to those skilled in the art that these specific details are not required in every case and that, in some instances, well-known structures and components are shown in block diagram form for clarity of presentation.

In the description of embodiments herein, numerous specific details are set forth, such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

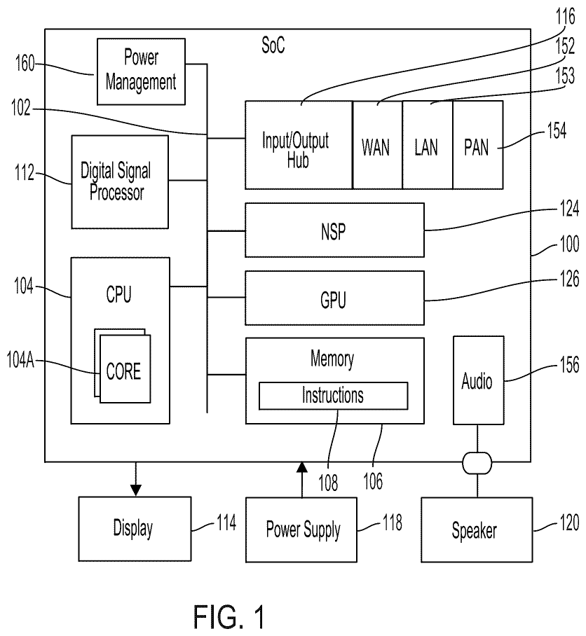

FIG. 1 shows a block diagram of a system-on-chip (SoC) configured for performing signal processing according to one or more aspects of this disclosure. The SoC 100 may include several components coupled together through a bus 102, which may be a network-on-a-chip (NoC) or a plurality of NOCs interconnecting various components. For example, although FIG. 1 illustrates several components coupled to the bus 102, the several components may be coupled to different busses with additional busses connecting the different busses to provide a path for communication between the components.

One example component in the SoC 100 is a digital signal processor 112 for signal processing. The DSP 112 may process audio signals and may include hardware customized for performing a limited set of operations on specific kinds of data, such as audio data. For example, a DSP may include transistors coupled together to perform operations on streaming data and use memory architectures and/or access techniques to fetch multiple data or instructions concurrently. Such configurations may allow the DSP 112 to operate on real-time data, such as video data, audio data, or modem data, in a power-efficient manner.

The SoC 100 also includes a central processing unit (CPU) 104 and a memory 106 storing instructions 108 (e.g., a memory storing processor-readable code or a non-transitory computer-readable medium storing instructions) that may be executed by a processor of the SoC 100. The CPU 104 may be a single central processing unit (CPU) or a CPU cluster comprising two or more cores such as core 104A. The CPU 104 may include hardware capable of performing generic operations on many kinds of data, such as hardware capable of executing instructions from the Advanced RISC Machines (ARM®) instruction set, such as ARM v8 and ARM v9. For example, a CPU 104 may include transistors coupled together to perform operations for supporting executing an operating system 220 and user applications (e.g., a camera application, a multimedia application, a gaming application, a productivity application, a messaging application, a videocall application, an audio recording application, a video recording application). The CPU 104 may execute instructions 108 retrieved from the memory 106. In some embodiments, the CPU 104 executing an operating system 220 may coordinate execution of instructions by various components within the SoC 100. For example, the CPU 104 may retrieve instructions 108 from memory 106 and execute the instructions on the DSP 112.

The SoC 100 may further include a neural signal processor (NSP) 124 for executing machine learning (ML) models relating to multimedia applications. The NSP 124 may include hardware configured to perform and accelerate convolution operations involved in executing machine learning algorithms. For example, the NSP 124 may improve performance when executing predictive models such as artificial neural networks (ANNs) (including multilayer feedforward neural networks (MLFFNN), the recurrent neural networks (RNN), and/or the radial basis functions (RBF)). The ANN executed by the NSP 124 may access predefined training weights stored in the memory 106 for performing operations on user data.

The SoC 100 may be coupled to a display 114 for interacting with a user. The SoC 100 may also include a graphics processing unit (GPU) 126 for rendering images on the display 114. In some embodiments, the CPU 104 may perform rendering to the display 114 without a GPU 126. In some embodiments, the GPU 126 may be configured to execute instructions for performing operations unrelated to rendering images, such as for processing large volumes of datasets in parallel.

Processing algorithms, techniques, and methods may be executed by at least one processor of the SoC 100, which may include execution by all steps on one of the processors (e.g., DSP 112, CPU 104, NSP 124, GPU 126) or may include execution of steps across a combination of one or more of the processors (e.g., DSP 112, CPU 104, NSP 124, GPU 126). In some embodiments, at least a DSP 112 or a CPU 104 executes instructions to perform various operations described herein, including determining a mitigation level based on the battery power available over an instantaneous and average load duration. There can be multiple mitigation levels.

The SoC 100 may also include hardware configured to manage power consumption by the SoC 100 and components therein. For example, power management 160 may be coupled to components of the SoC, such as through the bus 102. Power management 160 may include an application-specific integrated circuitry (ASIC), logic circuitry configured to perform defined operations, and/or a microcontroller executing firmware to perform power management operations. The power management 160 may monitor the power supply 118 and control one or more parameters of operation of the SoC, such as parameters of operation of the CPU 104, the NSP 124, the GPU 126, and other components of the SoC 100. In some embodiments, the power management 160 may be performed partially or entirely in software executing on one or more processors of the SoC 100.

Input/output components may be coupled to the SoC 100 through an input/output (I/O) hub 116. An example of a hub 116 is an interconnect to a peripheral component interconnect express (PCIe) bus. Example components coupled to hub 116 may be components used for interacting with a user, such as a touch screen interface and/or physical buttons. Some components coupled to hub 116 may also include network interfaces for communicating with other devices, including a wide area network (WAN) adaptor (e.g., WAN adaptor 152), a local area network (LAN) adaptor (e.g., LAN adaptor 153), and/or a personal area network (PAN) adaptor (e.g., PAN adaptor 154). A WAN adaptor 152 may be a 4G LTE or a 5G NR wireless network adaptor. A LAN adaptor 153 may be an IEEE 802.11 WiFi wireless network adapter. A PAN adaptor 154 may be a Bluetooth wireless network adaptor. Each of the WAN adaptor 152, LAN adaptor 153, and/or PAN adaptor 154 may be coupled to an antenna that may be shared by each of the adaptors 152, 153, and 154, or coupled to multiple antennas configured for primary and diversity reception and/or configured for receiving specific frequency bands. In some embodiments, the WAN adaptor 152, LAN adaptor 153, and/or PAN adaptor 154 may share circuitry, such as portions of a radio frequency front end (RFFE).

Audio circuitry 156 may be integrated in SoC 100 as dedicated circuitry for coupling the SoC 100 to a speaker 120 external to the SoC 100, which may be a transducer such as a speaker (either internal to or external to a device incorporating the SoC 100) or headphones. The audio circuitry 156 may include coder/decoder (CODEC) functionality for processing digital audio signals. The audio circuitry 156 may further include one or more amplifiers (e.g., a class-D amplifier) for driving a transducer coupled to the SoC 100 for outputting sounds generated during execution of applications by the SoC 100. Functionality related to audio signals described herein may be performed by a combination of the audio circuitry 156 and/or other processors of the SoC (e.g., CPU 104, DSP 112, GPU 126, NSP 124).

The SoC 100 may couple to external devices outside the package of the SoC 100. For example, the SoC 100 may be coupled to a power supply 118, such as a battery or an adaptor to couple the SoC 100 to an energy source. The signal processing described herein may be adapted to and achieve power efficiency to support operation of the SoC 100 from a limited-capacity power supply 118 such as a battery. For example, operations may be performed on a portion of the SoC 100 configured for performing the operation at a lowest power consumption. As another example, operations themselves are performed in a manner that reduces an amount of computations to perform the operation, such that the algorithm is optimized for extending the operational time of a device while powered by a limited-capacity power supply 118. In some embodiments, the operations described herein may be configured based on a type of power supply 118 providing energy to the SoC 100. For example, a first set of operations may be executed to perform a function when the power supply 118 is a wall adaptor. As another example, a second set of operations may be executed to perform a function when the power supply 118 is a battery. The power supply 118 may be a Si-anode battery.

The SoC 100 may also include or be coupled to additional features or components that are not shown in FIG. 1. Although components are shown integrated as a single SoC 100, which may include all components built on a single semiconductor die with a common semiconductor substrate, other arrangements of the illustrated blocks different number of dies, substrates, and/or packages may be arranged to accomplish the same functionality described in this disclosure.

The memory 106 may include a non-transient or non-transitory computer readable medium storing computer-executable instructions as instructions 108 to perform all or a portion of one or more operations described in this disclosure. The instructions 108 may include a multimedia application (or other suitable application such as a messaging application) to be executed by the SoC 100 that records, processes, or outputs audio signals. The instructions 108 may also include other applications or programs executed by the SoC 100, such as an operating system 220 and applications other than for multimedia processing.

In addition to instructions 108, the memory 106 may also store audio data. The SoC 100 may be coupled to an external memory and configured to access the memory for writing output audio files for later playback or long-term storage. For example, the SoC 100 may be coupled to a flash storage device comprising NAND memory for storing video files (e.g., MP4-container formatted files) including audio tracks and/or storing audio recordings (e.g., MPEG-1 Layer 3 files, also referred to as MP3 files). Portions of the video or audio files may be transferred to memory 106 for processing by the SoC 100, with the resulting signals after processing encoded as video or audio files in the memory 106 for transfer to the long-term storage.

While the SoC 100 is referred to in the examples herein for performing aspects of the present disclosure, some device components may not be shown in FIG. 1 to prevent obscuring aspects of the present disclosure. Additionally, other components, numbers of components, or combinations of components may be included in a suitable device for performing aspects of the present disclosure. As such, the present disclosure is not limited to a specific device or configuration of components, including the device 100.

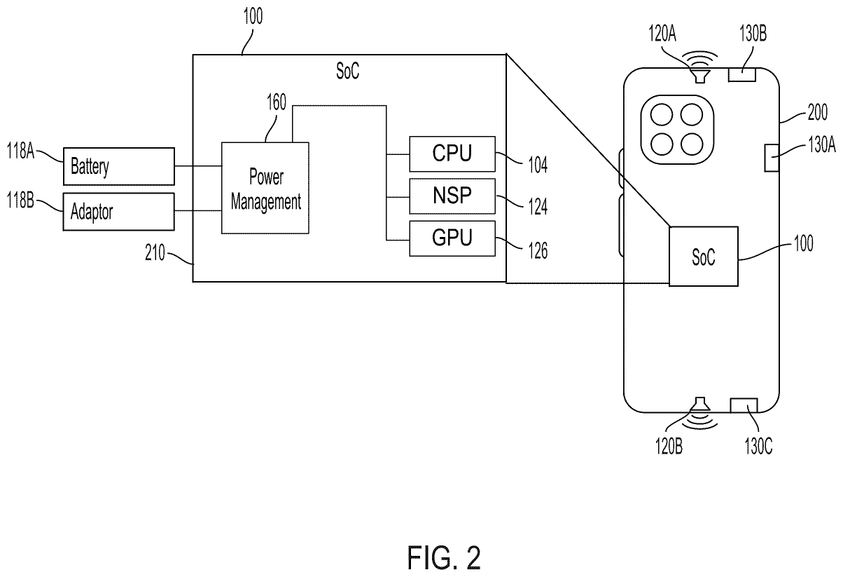

The SoC of FIG. 1 may be operated to obtain improved power management, device performance, and/or improved user experience by proactively determining battery power available over an instantaneous and average load. In some example embodiments that follow, a battery power available (BPA) value may represent an amount of power that can be drawn out of the battery at a given time over a specified time duration. For example, a BPA value may reflect a number of watts that the battery can provide over 200 milliseconds or over 2 seconds. The BPA may dynamically indicate impending power shortage conditions, particularly in extreme operating conditions. The BPA value may be used as an envelope for power management of the device by proportionally allocating the BPA to various components. One example integration of aspects of this disclosure into a wireless device are shown in FIG. 2 and described below.

FIG. 2 is a block diagram illustrating some components involved in proactively determining battery power available over an instantaneous and average load and adjusting parameters for device performance according to one or more aspects of the disclosure. SoC 100 may include the power manager 160, which may be part of or separate from a power management integrated circuit (PMIC), for controlling the parameters of operation of a CPU 104, NSP 124, and a GPU 126. The parameters of operation include one or more processor frequencies and/or a number of active processor cores, in any combination, of each of the CPU 104, NSP 124, and GPU 126. Adjusting device performance may include capping processor frequency or isolating a number of processor cores (e.g., by activating headswitches and/or footswitches). The power manager 160 may implement a plurality of mitigation levels to decide when to adjust parameters for device performance based on predictions for battery power available (BPA), as described in embodiments below. The power manager 160 may consider whether the device is receiving a voltage from a wall adaptor 118B coupling the SoC 100 to an energy source (and/or a wattage capability of the wall adaptor 118B) in determining mitigation levels or adjustments to parameters for device performance. The power manager 160 may also receive the voltage level and/or other parameters from the battery 118A.

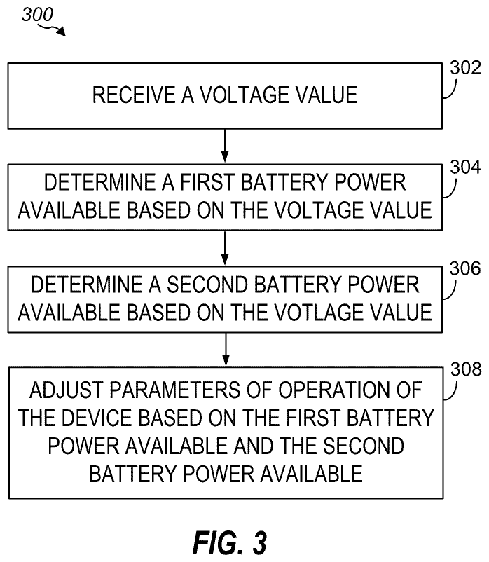

The device of FIG. 2 may be configured to perform operations described with reference to FIG. 3 to proactively determine battery power available over an instantaneous and average load and adjust parameters for device performance according to one or more aspects of this disclosure. FIG. 3 shows a flow chart of an example method for proactively determining battery power available over an instantaneous and average load and adjusting parameters for device performance according to one or more aspects of this disclosure. The operations of FIG. 3 may result in improved battery and device performance, which results in an improved user experience. Each of the operations described with reference to FIG. 3 may be performed by one or a combination of the processors of the SoC 100.

The operations described in FIG. 3 may be incorporated into a battery gauge for a mobile device operated, at least part of the time, from a battery power source. The battery gauge periodically collects battery voltage, battery current, and battery temperature measurements. Prior to system boot of the mobile device, the battery gauge collects battery voltage, current, and temperature while output current from the battery is low and the battery voltage is settled. The initial set of readings, from the low-current drain condition of the battery, is used to determine an OCV value, which maps to a battery state-of-charge (SOC) for the given temperature. The SOC value may be used to reference a look up table to identify a set of parameter values, including R int and C int, corresponding to the battery for battery power available (BPA) determinations described in FIG. 3. Subsequent battery voltage, current, and temperature measurements are then used in a multi-stage extended Kalman filter based error minimization techniques to update the parameter values of OCV, Vint, and R int that may be used to update the battery power available (BPA) determinations described in blocks 302, 304, and 306 below.

The look-up tables may be determined based on measurements of running charge and discharge curves for a battery model installed in the mobile device or a suitably similar battery model with similar electrical characteristics. The measurements include pushing or pulling of a specific percentage of capacity in or out of the battery, then immediately stopping the current, while monitoring battery voltage, current and temperature. After terminating the current, the battery is allowed to relax to the point where it has adequately settled. Once data is collected over the entire charge and discharge SOC range, at each specified temperature, the data is processed to minimize the curve fit error for a Randles' second order model at each predetermined point on the SOC curves. The processing provides battery capacity, and OCV, R int (ESR, Rslow, Rfast), and C int (Cslow and Cfast) as a function of SOC and temperature.

Using data from an initial calibration of the battery, the battery gauge updates all parameters (e.g., OCV, R int, C int) for the battery at a fixed or dynamic timing (e.g., on a 1 Hz interval) for a SOC update. The battery gauge's parameters may be used in the method described below in blocks 302, 304, 306, and 308 to determine battery power available (BPA).

At block 302, a voltage value is received from a device (e.g., V_{batt}). When the load on the battery increases, such as due to increased user operations, the voltage at the battery may be reduced. If the battery voltage V batt falls below a minimum voltage V min the device may experience brown out resulting in errors or device failures. V min may be the larger of the lowest voltage the battery can operate and the lowest voltage the system ICs can operate.

At block 304, a first battery power available (BPA) value is determined. This first battery power available value corresponds to the power that is available from the battery during a first load duration. The first battery power available value may be calculated as the product of the voltage received at block 302 and the corresponding maximum current able to be drawn from the device over a first load duration, such as 100 milliseconds. The first battery power available value may represent an amount of power that can be drawn out of the battery over the 100 milliseconds in the immediate future. The first battery power value available may be determined based on a subset of second-order battery parameters. Second order battery parameters may include an open circuit voltage (OCV), a battery internal resistance (Rᵢₙₜ), and a total resistance and capacitance corresponding to fast and slow time constant elements.

Under a short timescale the current drawn from the battery may primarily depend on a subset of second order battery parameters. The subset of parameters that the first battery power available may be based on include an open circuit voltage and a battery internal resistance. The first battery power available value may be determined based on a voltage drop over a modeled battery internal resistance (Rᵢₙₜ), wherein a voltage drop across the modeled battery internal resistance is Vint. For example, the first battery power available value (BPA₁) may be calculated as follows:

$$B P {A}_{1} = \frac{( OCV - {V}_{i n t} - {V}_{min} ) * {V}_{min}}{{R}_{i n t}}$$

At block 306, a second battery power available value is determined. This second battery power available value corresponds to a power that is predicted to be available from the battery during a future load duration of a different duration than the first battery power available value. The second battery power available value may be calculated as the product of the voltage received at block 302 and the corresponding maximum current able to be drawn from the device over a longer time duration, such as 2 seconds. The second battery power available value may be based on the second-order battery parameters. The second battery power available may be based on at least some or all of the second-order battery parameters. The second battery power available value may also be based on a total battery impedance (Zₜₒₜₐₗ) corresponding to the total resistance and capacitance for fast and slow time constant elements of the battery. The second battery power available value may be based on a voltage drop across the battery internal resistance (V_{IR}). The voltage drop across the second-order battery parameters may include the voltage drop across the total resistance and capacitance corresponding to fast and slow time constants elements of the battery. For example, the second battery power available may be calculated as follows:

$$B P {A}_{2} = \frac{( OCV - {V}_{I R} - {V}_{min} ) * {V}_{min}}{{Z}_{t o t a l}}$$

At block 308, the device uses the first battery power available value and second battery power available value to adjust parameters of operation of the device. Adjusting parameters of operation can include capping or otherwise setting the operating frequency of any processor in the device such as the CPU 104, GPU 126, or NSP 124. These operational parameters may include the number of active cores within a processor. For example, depending on a first and second battery power available value one of many cores within the CPU 104 may be isolated for operation with the other cores shutdown. As another example, all cores within the CPU 104 may be active under higher first and second battery power available levels.

In some embodiments, a mitigation scheme with multiple rules may be applied for the adjusting of the parameters of operation at block 308. For example, a first mitigation level may include de-activating one large core of a multi-core CPU and capping a frequency of each of the processors in the SoC 100 to a particular threshold frequency when the first battery power available (BPA) is below a first power threshold and the second BPA is below a second power threshold. As another example, a second mitigation level may include de-activating all large cores of a multi-core CPU and capping a frequency of each of the processors in the SoC to a lower threshold than the thresholds of the first mitigation level when the first BPA is below a third power thresholds and the second BPA is below a fourth power threshold. As a further example, a third mitigation level may include de-activating all large cores of a multi-core CPU and capping a frequency of each of the processors in the SoC to a lower threshold than the thresholds of the second mitigation level when the first BPA is below a fifth power threshold and the second BPA is below a sixth power threshold, in which the fifth power threshold is lower than a third power threshold that is lower than a first power threshold and the sixth power threshold is lower than a fourth power threshold that is lower than a second power threshold. The mitigation scheme may be de-activated regardless of the first and BPA values when a charger with a charging wattage above a charging threshold level (e.g., 7.5 Watts) is coupled to the device with the SoC 100.

The increased battery optimization achievable through the use of battery power available (BPA) determinations described according to different embodiments described above allow the use of different battery chemistries within mobile devices. For example, the use of Silicon Anode batteries, which have an anode doped with 4-10% Silicon, or more generally 2-25% Silicon, may provide batteries with higher energy density that is only available at lower battery levels corresponding to lower voltage levels. The algorithms for power management based on BPA values, including two BPA values, provide improved power management when operating a device at lower voltage battery levels while reducing or preventing the possibility of brown-outs that affect device performance.

The operations described with reference to blocks 302, 304, 306, and 308 of FIG. 3 may be performed on a digital signal processor (DSP), such as DSP 112 of the SoC 100 illustrated in FIG. 1. However, the operations may alternatively be performed by one or more of the processors of FIG. 1, including one or more of the CPU 104, the DSP 112, the GPU 126, or the NSP 124. In another example, the processor performing the operations of blocks 302, 304, 306, and/or 308 may be dedicated logic circuitry for performing certain operations.

The operations described with reference to blocks 302, 304, 306 may be repeated to provide an updated first and/or second BPA value for controlling device power consumption at block 308. In some embodiments, the update of blocks 302, 304, and 306 may be performed using an updated value from a subset of current, voltage, and/or temperature. For example, a new voltage measurement may be obtained compared to a previous execution of blocks 302, 304, and 306, and the operations of blocks 302, 304, and 306 may be repeated with the same voltage value and the previous current and temperature value.

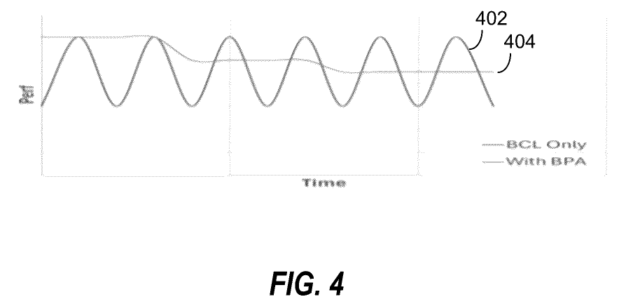

An example operation of the use of battery power available calculations in power management is explained with reference to FIG. 4. FIG. 4 is a graph illustrating device performance over time according to some embodiments of the disclosure. The graph illustrates the performance of the device over time when power management is performed using conventional current limiting as shown with line 402 and power management is performed using battery power available determinations as shown with line 404. The line 402 indicates performance increases until a battery limit is reached, upon which current is severely limited through a reduced battery current limit, after which the performance is allowed to increase until a new limit is reached. This results in an oscillating performance of the device as shown in line 402. The battery power available determination according to embodiments of this disclosure provides a more level and consistent performance for the device shown in line 404, which improves user experience when using the device by reducing the number of apparent “stalls” the device experiences. Additionally, the reduced oscillations increase battery life and extend battery life by allowing untapped capacity from being able to operate at lower battery voltage levels.

In one or more aspects, techniques for dynamically indicating impending power shortage conditions may include additional aspects, such as any single aspect or any combination of aspects described below or in connection with one or more other processes or devices described elsewhere herein. In a first aspect, a method for dynamically indicating impending power shortage conditions may include determining a first battery power available based on a voltage, a current, and a temperature value for a first future load duration; determining a second battery power available based on the voltage, the current, and the temperature values for a second future load duration that is different from the first future load duration; and adjusting at least one parameter of operation of a device powered from a battery based on the first battery power available and the second battery available.

In a second aspect, in combination with the first aspect, the method further comprises determining a set of second-order battery model parameters based on the voltage, the current, and the temperature values, wherein the first battery power available is based on a subset of the set of second-order battery model parameters, and wherein the second battery power available is based on the set of second-order battery model parameters.

In a third aspect, in combination with one or more of the first aspect or the second aspect, the set of second-order battery model parameters comprises an open circuit voltage (OCV), an internal resistance (R int), and an internal capacitance (C int).

In a fourth aspect, in combination with one or more of the first aspect through the third aspect, the first battery power available is computed as

$$B P {A}_{1} = \frac{( OCV - {V}_{Int} - {V}_{min} ) * {V}_{min}}{{R}_{Int}} ,$$

wherein V int is a modeled internal voltage drop within the battery and V min is a voltage level of the battery for device operation.

In a fifth aspect, in combination with one or more of the first aspect through the fourth aspect, the second battery power available is determined as

$$B P {A}_{2} = \frac{( OCV - {V}_{IR} - {V}_{min} ) * {V}_{min}}{{Z}_{t o t a l}} ,$$

wherein V min is a voltage level of the battery for device operation and Ztotal is a battery impedance of the battery.

In a sixth aspect, in combination with one or more of the first aspect through the fifth aspect, the first future load duration is at least an order of magnitude smaller than the second future load duration.

In a seventh aspect, in combination with one or more of the first aspect through the sixth aspect, adjusting at least one parameter of operation of the device powered from the battery is further based on a charger status.

In an eighth aspect, an apparatus, comprises a memory storing processor-readable code; and one or more processors coupled to the memory, the one or more processors configured to execute the processor-readable code to cause the one or more processors to: determine a first battery power available based on a voltage, a current, and a temperature value for a first future load duration; determine a second battery power available based on the voltage, the current, and the temperature values for a second future load duration that is different from the first future load duration; and adjust at least one parameter of operation of a device powered from a battery based on the first battery power available and the second battery available.

In a ninth aspect, in combination with one the eight, the apparatus comprises further comprising the one or more processors configured to execute the processor-readable code to cause the one or more processors to: determine a set of second-order battery model parameters based on the voltage, the current, and the temperature values, wherein the first battery power available is based on a subset of the set of second-order battery model parameters, and wherein the second battery power available is based on the set of second-order battery model parameters.

In a tenth aspect, in combination with one or more of the eighth aspect through the ninth aspect, the set of second-order battery model parameters comprises an open circuit voltage (OCV), an internal resistance (R int), and an internal capacitance (C int).

In an eleventh aspect, in combination with one or more of the eighth aspect through the tenth aspect, the first battery power available is computed as

$$B P {A}_{1} = \frac{( OCV - {V}_{Int} - {V}_{min} ) * {V}_{min}}{{R}_{Int}} ,$$

wherein V int is a modeled internal voltage drop within the battery and V min is a voltage level of the battery for device operation.

In a twelfth aspect, in combination with one or more of the eighth aspect through the eleventh aspect, the second battery power available is determined as

$$BP {A}_{2} = \frac{( OCV - {V}_{IR} - {V}_{min} ) * {V}_{min}}{{Z}_{t o t a l}} ,$$

wherein V min is a voltage level of the battery for device operation and Ztotal is a battery impedance of the battery.

In a thirteenth aspect, in combination with one or more of the eighth aspect through the twelfth aspect, the first future load duration is at least an order of magnitude smaller than the second future load duration.

In a fourteenth aspect, in combination with one or more of the eighth aspect through the thirteenth aspect, adjusting at least one parameter of operation of the device powered from the battery is further based on a charger status.

In a fifteenth aspect, a mobile device comprises a silicon anode battery, a memory storing processor-readable code; and one or more processors coupled to the memory, the one or more processors configured to execute the processor-readable code to cause the one or more processors to: determine a first battery power available of the silicon anode battery based on a voltage, a current and a temperature value for a first future load duration; determine a second battery power available of the silicon anode battery based on the voltage, the current, and the temperature values for a second future load duration that is different from the first future load duration; and adjusting at least one parameter of operation of the mobile device powered from the silicon anode battery based on the first battery power available and the second battery available.

In a sixteenth aspect, in combination with the fifteenth aspect, the mobile device further comprises the one or more processors configured to execute the processor-readable code to cause the one or more processors to: determine a set of second-order battery model parameters based on the voltage, the current, and the temperature values, wherein the first battery power available is based on a subset of the set of second-order battery model parameters, and wherein the second battery power available is based on the set of second-order battery model parameters.

In a seventeenth aspect, in combination with one or more of the fifteenth aspect through the sixteenth aspect, the set of second-order battery model parameters comprises an open circuit voltage (OCV), an internal resistance (R int), and an internal capacitance (C int).

In an eighteenth aspect, in combination with one or more of the fifteenth aspect through the seventeenth aspect, the first battery power available is computed as

$$B P {A}_{1} = \frac{( OCV - {V}_{Int} - {V}_{min} ) * {V}_{min}}{{R}_{Int}} ,$$

wherein V int is a modeled internal voltage drop within the silicon anode battery and V min is a voltage level of the silicon anode battery for device operation.

In a nineteenth aspect, in combination with one or more of the fifteenth aspect through the eighteenth aspect, the second battery power available is determined as

$$B P {A}_{2} = \frac{( OCV - {V}_{IR} - {V}_{min} ) * {V}_{min}}{{Z}_{t otal}} ,$$

wherein V min is a voltage level of the silicon anode battery for device operation and Zₜₒₜₐₗ is a battery impedance of the silicon anode battery.

In a twentieth aspect, in combination with one or more of the fifteenth aspect through the nineteenth aspect, the first future load duration is at least an order of magnitude smaller than the second future load duration.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it is appreciated that throughout the present application, discussions using terms such as “accessing,” “receiving,” “sending,” “using,” “selecting,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices. The use of different terms referring to actions or processes of a computer system does not necessarily indicate different operations. For example, “determining” data may refer to “generating” data. As another example, “determining” data may refer to “retrieving” data.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (e.g., application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to the Figures referenced above include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or algorithm disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc wherein disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A method, comprising:
determining a first battery power available based on a voltage, a current, and a temperature value for a first future load duration;
determining a second battery power available based on the voltage, the current, and the temperature values for a second future load duration that is different from the first future load duration; and
adjusting at least one parameter of operation of a device powered from a battery based on the first battery power available and the second battery power available.

2. The method of claim 1, further comprising determining a set of second-order battery model parameters based on the voltage, the current, and the temperature value,
wherein the first battery power available is based on a subset of the set of second-order battery model parameters, and
wherein the second battery power available is based on the set of second-order battery model parameters.

3. The method of claim 2, wherein the set of second-order battery model parameters comprises an open circuit voltage (OCV), an internal resistance (R int), and an internal capacitance (C int).

4. The method of claim 3, wherein the first battery power available is computed as
$$B P {A}_{1} = \frac{( OCV - {V}_{Int} - {V}_{min} ) * {V}_{min}}{{R}_{Int}} ,$$
wherein V int is a modeled internal voltage drop within the battery and V min is a lower voltage level limit of the battery for device operation.

5. The method of claim 3, wherein the second battery power available is determined as
$$B P {A}_{2} = \frac{( OCV - {V}_{IR} - {V}_{min} ) * {V}_{min}}{{Z}_{t otal}} ,$$
wherein V min is a lower voltage level limit of the battery for device operation and Ztotal is a battery impedance of the battery.

6. The method of claim 1, wherein the first future load duration is at least an order of magnitude smaller than the second future load duration.

7. The method of claim 1, wherein adjusting at least one parameter of operation of the device powered from the battery is further based on a charger status.

8. An apparatus, comprising:
a memory storing processor-readable code; and
one or more processors coupled to the memory, the one or more processors configured to execute the processor-readable code to cause the one or more processors to:
determine a first battery power available based on a voltage, a current, and a temperature value for a first future load duration;
determine a second battery power available based on the voltage, the current, and the temperature values for a second future load duration that is different from the first future load duration; and
adjust at least one parameter of operation of a device powered from a battery based on the first battery power available and the second battery power available.

9. The apparatus of claim 8, wherein the one or more processors are configured to execute the processor-readable code to cause the one or more processors to:
determine a set of second-order battery model parameters based on the voltage, the current, and the temperature value,
wherein the first battery power available is based on a subset of the set of second-order battery model parameters, and
wherein the second battery power available is based on the set of second-order battery model parameters.

10. The apparatus of claim 9, wherein the set of second-order battery model parameters comprises an open circuit voltage (OCV), an internal resistance (R int), and an internal capacitance (C int).

11. The apparatus of claim 10, wherein the first battery power available is computed as
$$B P {A}_{1} = \frac{( OCV - {V}_{Int} - {V}_{min} ) * {V}_{min}}{{R}_{Int}} ,$$
wherein V int is a modeled internal voltage drop within the battery and V min is a lower voltage level limit of the battery for device operation.

12. The apparatus of claim 10, wherein the second battery power available is determined as
$$B P {A}_{2} = \frac{( OCV - {V}_{IR} - {V}_{min} ) * {V}_{min}}{{Z}_{t otal}} ,$$
wherein V min is a lower voltage level limit of the battery for device operation and Ztotal is a battery impedance of the battery.

13. The apparatus of claim 8, wherein the first future load duration is at least an order of magnitude smaller than the second future load duration.

14. The apparatus of claim 8, wherein adjusting at least one parameter of operation of the device powered from the battery is further based on a charger status.

15. A mobile device, comprising:
a silicon anode battery,
a memory storing processor-readable code; and
one or more processors coupled to the memory, the one or more processors configured to execute the processor-readable code to cause the one or more processors to:
determine a first battery power available of the silicon anode battery based on a voltage, a current and a temperature value for a first future load duration;
determine a second battery power available of the silicon anode battery based on the voltage, the current, and the temperature values for a second future load duration that is different from the first future load duration; and
adjusting at least one parameter of operation of the mobile device powered from the silicon anode battery based on the first battery power available and the second battery power available.

16. The mobile device of claim 15, wherein the one or more processors are configured to execute the processor-readable code to cause the one or more processors to:
determine a set of second-order battery model parameters based on the voltage, the current, and the temperature value,
wherein the first battery power available is based on a subset of the set of second-order battery model parameters, and
wherein the second battery power available is based on the set of second-order battery model parameters.

17. The mobile device of claim 16, wherein the set of second-order battery model parameters comprises an open circuit voltage (OCV), an internal resistance (R int), and an internal capacitance (C int).

18. The mobile device of claim 17, wherein the first battery power available is computed as
$$B P {A}_{1} = \frac{( OCV - {V}_{Int} - {V}_{min} ) * {V}_{min}}{{R}_{Int}} ,$$
wherein V int is a modeled internal voltage drop within the silicon anode battery and V min is a lower voltage level limit of the silicon anode battery for device operation.

19. The mobile device of claim 17, wherein the second battery power available is determined as
$$B P {A}_{2} = \frac{( OCV - {V}_{IR} - {V}_{min} ) * {V}_{min}}{{Z}_{t otal}} ,$$
wherein V min is a lower voltage level limit of the silicon anode battery for device operation and Ztotal is a battery impedance of the silicon anode battery.

20. The mobile device of claim 15, wherein the first future load duration is at least an order of magnitude smaller than the second future load duration.
